(19) United States
(12) Patent Application Publication
(10) Pub. No.: US 2005/0194686 A1
(43) Pub. Date: Sep. 8, 2005

(54) Semiconductor device and manufacturing method for the same

(75) Inventors: Yoshihide Iwazaki, Soraku-gun (JP); Shinji Suminoe, Tenri-shi (JP); Katsunobu Mori, Nara-shi (JP)

Correspondence Address: NIXON & VANDERHYE, PC, 901 NORTH GLEBE ROAD, 11TH FLOOR, ARLINGTON, VA, 22203, US

(73) Assignee: SHARP KABUSHIKI KAISHA, Osaka-shi (JP)

(21) Appl. No.: 11/072,238

(22) Filed: Mar. 7, 2005

(30) Foreign Application Priority Data
Mar. 8, 2004 (JP) 2004-063997

(51) Int. Cl. H01L 23/48; H01L 21/44

(52) U.S. Cl. 257/738; 438/613

(57) ABSTRACT

A semiconductor device according to the present invention comprises an electrode pad electrically conducted to an electric circuit formed on an element-formed surface of a silicon wafer; a wiring pattern re-wired by being electrically conducted to the electrode pad; and an oxide film formed on a surface of the wiring pattern, the oxide film being formed by subjecting the wiring pattern to oxidization. With the provision of oxide film, the semiconductor device prevents a decrease in reliability in terms of electric characteristic or the like, and also achieves reduction in fabrication cost compared to a conventional semiconductor device.

This Nonprovisional application claims priority under 35 U.S.C. § 119(a) on Patent Application No. 2004/063997 filed in Japan on Mar. 8, 2004, the entire contents of which are hereby incorporated by reference.

### FIELD OF THE INVENTION

The present invention relates to a semiconductor device in which a wiring pattern on a semiconductor wafer is bonded to an external electrode terminal, and also relates to a manufacturing method for the semiconductor device.

### BACKGROUND OF THE INVENTION

In recent years, a semiconductor device is further miniaturized, while its performance is improved, and therefore the device needs to be structured with high density. To meet this requirement, a semiconductor device often use a chip size package structure (CSP structure), in which external electrode terminals are aligned in the element-formed surface of a semiconductor chip in an area-array manner. This structure allows use of a larger number of external electrode terminals than those in a same-sized quad flat package structure (QFP structure). With this advantage, the CSP structure with the described alignment is the main stream of a high density surface-mounted semiconductor device.

In manufacturing such a CSP structure semiconductor device, a general conventional method uses a solder ball as an external electrode terminal. The use of solder ball has some advantages, such as less number of manufacturing processes, less equipment investment, and ease of manufacturing management. Further, as other benefit in use of solder ball, the size of the external electrode terminal can be more easily controlled, compared to the formation of a bump by printing of solder paste.

When mounted to the semiconductor chip, the solder ball is temporarily mounted to a predetermined position using a flux, and then is melted by reflow process, followed by cooling, so that the solder ball is bonded to a specific bonding region (land) formed on the element-formed surface of a semiconductor chip.

However, in the ball mounting process and the reflow process, the relative position of the solder ball and the land is not stable, thereby causing some problems, such as generation of a solder bridge between two adjacent solder balls.

In view of this problem, in conventional manufacturing, the periphery of the land is covered with a resin solder resist so as to fix the melted solder ball to the predetermined bonding region.

With reference to FIGS. 10 and 11, the following explains a method (Document 1) of preventing alignment error by providing resin solder resist on the peripheral surface of the land.

FIG. 10 shows a semiconductor device including a printed-wiring board on which a land 17 and a wiring pattern 5 are formed; and a solder resist layer 15 with a solder ball bonding hole 19 for exposing a part of the land 17, allowing the solder ball to be bonded to the wiring pattern 5.

Next, the foregoing mounting method is described with reference to FIGS. 11(a) and 11(b). FIG. 11(a) is a cross sectional view, taken along the line A-A of FIG. 10, for showing a cross section of the printed-wiring board 16, severed along one diameter direction 20b (shorter-diameter direction) of the oval-shaped land 17 shown in FIG. 10. FIG. 11(b) is a cross sectional view, taken along the line B-B of FIG. 10, for showing a cross section of the printed-wiring board 16, severed along another diameter direction 20a (longer-diameter direction) of the land 17 shown in FIG. 10.

In the diameter direction 20b, there is a gap 18 between each end of the land 17 and an inner wall of the bonding hole 19. Therefore, the solder ball 7 is bonded to the entire plane of land 17 in the diameter direction 20b. In this manner, the stress is not applied intensively to a part of the solder ball 7, thereby ensuring a certain strength of bonding.

Further, in the diameter direction 20a that is orthogonal to the diameter direction 20a, each end of the land 17 is covered by the solder resist 15.

Therefore, when the solder ball 7 is melted and bonded onto the land 17, the flow of the melted solder ball 7 in the diameter direction 20a is stopped by the wall of the bonding hole 19 formed on the upper surface of the land 17, allowing the solder ball 7 to be bonded on the center of the land 17, thus preventing alignment error of the solder ball.

Moreover, the wiring pattern 5 is connected to the end portion of the land 17 covered by the solder resist layer 15. With this arrangement, the solder ball 7 is placed in accordance with the bonding hole 19, and is properly positioned without being shifted toward the wiring pattern 5 covered by the solder resist layer 15.

However, in the foregoing conventional method, the solder resist layer 15 is made of an epoxy-type solder resist, and the epoxy-type solder resist has high water-absorption property, and therefore causes expansion, exfoliation, or a crack under high temperature and high humidity. With such a characteristic, the use of epoxy-type solder resist may result in a problem, for example, failure in securely preventing alignment error of the solder ball 7.

In view of this defect, a polyimide-type resin has been suggested for the material of the solder resist layer 15 with its superior heat-resistance, moisture-resistance and adhesion than the epoxy-type resin. When the polyimide-type resin is used as the material of the solder resist layer 15, the alignment pattern is formed as a polyamide acid, that is precursor of polyimide, by performing development, and then the pattern of polyamide acid is cyclized by heat to create the polyimide-type resin. This method generally requires high-temperature curing process at 300° C. or above.

Meanwhile, after forming the solder ball 7 as an external electrode terminal, the solder resist layer 15 becomes a component of the semiconductor device, and is mounted with the device to the printed-wiring board or the like. Here, after the device is mounted to the printed-wiring board, in a general method, an underfill material is injected between the protection film layer on the surface of semiconductor device and the printed-wiring board, so as to improve mounting reliability of the semiconductor device to the printed-wiring board.

At this stage, there are plural boundaries exist between different pairs of materials, such as the wiring/protection layers, the solder resist layer, the underfill layer and the like. In such a lamination in which a plurality of layers made of different materials are stacked and bonded one another, decrease in bonding reliability for each boundary due to stress or moisture absorption is a generally known defect.

[Document 1] Japanese Laid-Open Patent Application Tokukaihei 09-232723 (published on Sep. 5, 1997)

[Document 2] Japanese Laid-Open Patent Application Tokukai 2001-144223 (published on May 25, 2001)

Document 2 discloses a chip size package in which an external electrode terminal is formed on an end portion of copper re-wiring. In this structure, the external electrode terminal is formed by plating, and therefore, after the copper re-wiring is formed, the copper re-wiring is coated for protection with a protection film (polyimide). Thereafter, the protection film is partly removed to create a region for connecting the external electrode terminal, allowing the external electrode terminal to be formed on the copper re-wiring through the region.

As described above, when a bump is formed by solder plating or the like, there are several defects, such as an increase in number of manufacturing process, an increase in equipment investment, a complex manufacturing control etc., compared to the method of mounting a solder ball to a chip.

Further, in the method described in Document 2, there is a problem of migration between the polyimide and the copper, thus requiring a barrier metal layer (Ni or Cr) on the copper re-wiring. This results in a cost rise.

Further, when adopting a method of forming the external electrode terminal by mounting a solder ball and performing a reflow process, instead of performing the foregoing plating method, if the solder ball is mounted for the reflow process without being covered by a protection film (polyimide), the solder ball spreads on the copper re-wiring, causing inadequate formation of the solder ball. Such a defect may be avoided by using an inorganic insulation film, such as a silicon oxide film, as a protection film; however the formation of the insulation film results in a cost rise.

### SUMMARY OF THE INVENTION

The object of the present invention is to provide a semiconductor device and manufacturing method thereof immune to decrease of reliability. The semiconductor device and the manufacturing method thereof also achieves reduction in fabrication cost compared to a conventional method due to omission of a solder resist process. More specifically, the present invention is arranged such that: when an external electrode terminal is formed in a conventional CSP structure semiconductor device, an oxide film is formed on an desired region of wiring through heating or chemical processing so as to prevent spread of the melted external electrode terminal. With this arrangement, the melted solder ball will not be shifted from a predetermined bonding range. In this way, the present invention allows omission of a resin solder resist layer used for covering the periphery of the land, and therefore realizes a structure free from expansion, exfoliation, crack of the solder resist layer. The present invention also allows omission of high-temperature process for curing the solder resist layer, thereby preventing a decrease in reliability on the solder resist layer or the boundaries of the solder resist layer due to stress or moisture absorption after mounting to the printed board. Since the solder resist process is omitted, the present invention achieves cost reduction.

In order to attain the foregoing object, a semiconductor device according to the present invention comprises: a substrate; an electric circuit formed on an element-formed surface of the substrate; an electrode pad electrically conducted to the electric circuit; a wiring pattern re-wired by being electrically conducted to the electrode pad; and an oxide film formed on a surface of the wiring pattern, the oxide film being formed by subjecting the wiring pattern to oxidization.

With this arrangement in which an oxide film is formed on the surface of the wiring pattern, when an external electrode terminal is formed on the wiring pattern from solder, the spread of the melted solder on the wiring pattern is prevented by the oxide film, that has a poor wettability with respect to the melted solder, thereby allowing secure formation of external electrode terminal on the wiring pattern.

Moreover, in the foregoing arrangement, since the oxide film is formed by subjecting the wiring pattern to oxidization, an extra process for forming the conventional insulation film is not required, thereby reducing fabrication cost.

In order to attain the foregoing object, a manufacturing method of semiconductor device according to the present invention comprises the steps of: (a) forming a wiring pattern for allowing electrical conduction of an electric pad and an external electrode terminal with respect to an element-formed surface of a wafer of a semiconductor device; (b) forming an oxide film on the wiring pattern in an area other than an area for the external electrode terminal, through oxidization of the wiring pattern; and (c) forming the external electrode terminal on the wiring pattern.

With this arrangement in which the oxide film is formed on the wiring pattern avoiding the mounting area of the external electrode terminal, when an external electrode terminal is formed on the wiring pattern from solder, the spread of the melted solder onto the wiring pattern upon formation of the external electrode terminal is prevented by the oxide film, that has a poor wettability with respect to the melted solder, thereby allowing secure formation of external electrode terminal on the wiring pattern.

Moreover, in the foregoing method, since the oxide film is formed by subjecting the wiring pattern to oxidization, an extra process for forming the conventional insulation film is not required, thereby reducing fabrication cost.

Additional objects, features, and strengths of the present invention will be made clear by the description below. Further, the advantages of the present invention will be evident from the following explanation in reference to the drawings.

### BRIEF DESCRIPTION OF THE DRAWINGS

FIGS. 1(a) through 1(d) are cross-sectional views illustrating some of the processing steps of a manufacturing method of a semiconductor device according to First Embodiment of the present invention.

FIGS. 2(a) through 2(e) are schematic cross sectional views illustrating other processing steps of the manufacturing method of semiconductor device.

FIG. 3(a) is the same view as FIG. 2(b) drafted again for reference.

FIGS. 3(b) through 3(e) are plan views for illustrating various shape examples of an oxide film formed on the semiconductor device.

FIGS. 4(a) through 4(c) are schematic cross sectional views showing different usages of the semiconductor device.

FIGS. 5(a) through 5(d) are cross-sectional views illustrating some of the processing steps of a manufacturing method of a semiconductor device according to Second Embodiment of the present invention.

FIGS. 6(a) through 6(e) are schematic cross sectional views illustrating other processing steps of the manufacturing method of semiconductor device.

FIGS. 7(a) through 7(d) are cross-sectional views illustrating some of the processing steps of a manufacturing method of a semiconductor device according to Third Embodiment of the present invention.

FIGS. 8(a) through 8(d) are cross-sectional views illustrating other processing steps of the manufacturing method of semiconductor device.

FIGS. 9(a) through 9(c) are cross-sectional views illustrating some of the processing steps of a manufacturing method of a semiconductor device according to Forth Embodiment of the present invention.

FIG. 10 is a plan view illustrating an example of a conventional semiconductor device.

FIG. 11(a) is a cross-sectional view, taken along the line A-A of the semiconductor device shown in FIG. 10.

FIG. 11(b) is a cross-sectional view, taken along the line B-B of the semiconductor device shown in FIG. 10.

### DESCRIPTION OF THE EMBODIMENTS

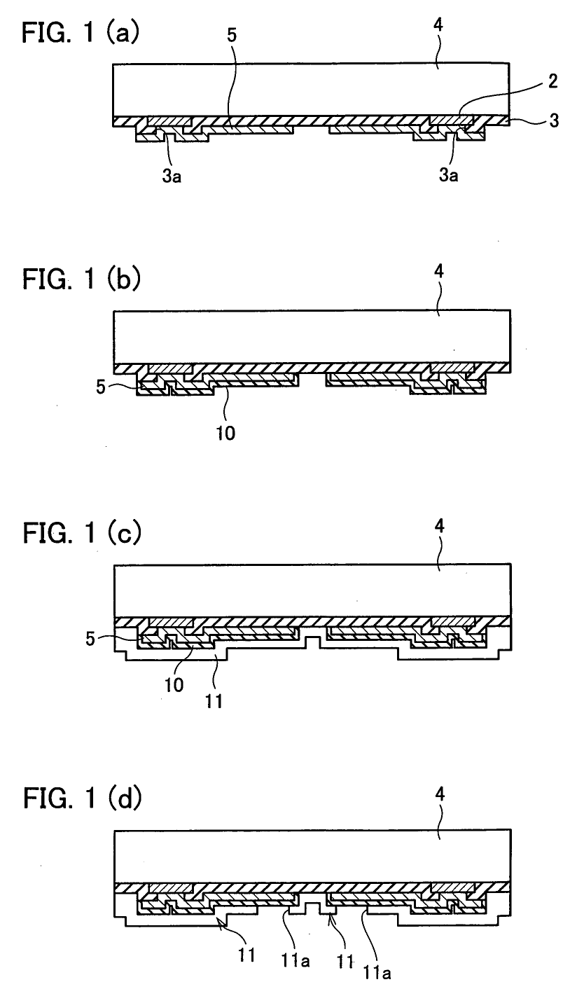

The following explains various Embodiments of a semiconductor device and a manufacturing method thereof according to the present invention with reference to FIGS. 1 through 9. In the following Embodiments, description of the manufacturing method of a semiconductor device also deals with a structure of a semiconductor device according to the present invention.

[First Embodiment]

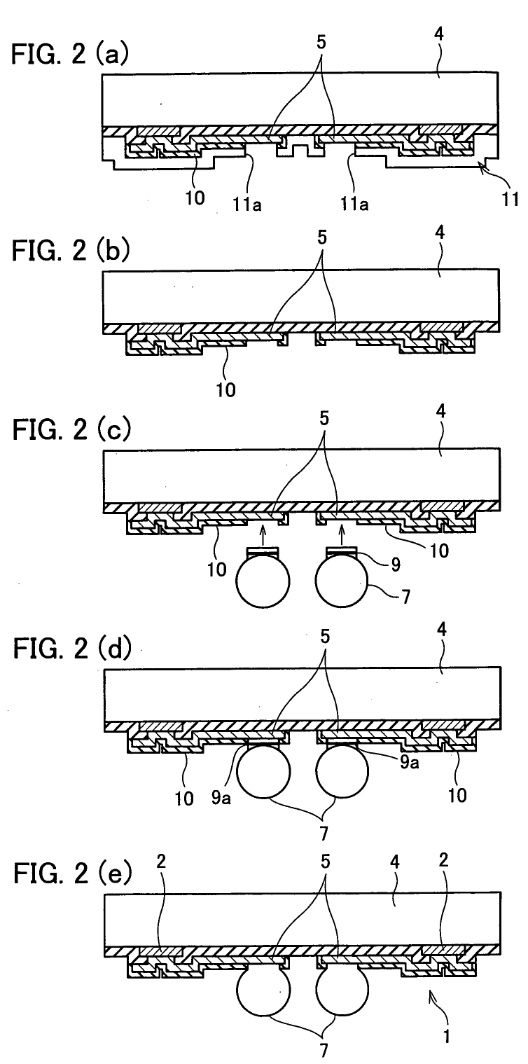

FIGS. 1(a) through 2(e) are cross-sectional views illustrating some of the processing steps of a manufacturing method of semiconductor device according to First Embodiment of the present invention. These figures each show a cross section in manufacturing of one of plural semiconductor chips (semiconductor devices) formed on a silicon wafer (substrate) 4. The following explains the manufacturing method according to First Embodiment of the present invention with reference to FIGS. 1(a) through 2(e).

FIG. 1(a) shows a silicon wafer 4 on which an electric circuit, such as an integrated circuit, and electrode pads for allowing external electrical conduction of the electric circuit are formed through an electric circuit forming step (not shown). The silicon wafer 4 further includes a protection film 3 with an opening on a desired one of the electrode pads 2 through a protection film forming step (not shown).

The silicon wafer 4 further includes a wiring pattern 5 as copper re-wiring that is electrically conducted and is formed on the electrode pad 2 through a wiring forming step (not shown). In this example, the wiring pattern 5 is the copper re-wiring that is electrically conducted and is formed on the electrode pad 2; however, the copper re-wiring may instead be other re-wiring made of a nickel or other metals, or a alloy either containing copper or nickel as the main component. The major component here refers to a substance whose content is greater than 50 mol %.

FIG. 1(b) shows an oxide film forming step for forming an oxide film 10 on the surface of wiring pattern 5, formed as re-arranged wiring on the element-formed surface of the silicon wafer 4. The silicon wafer 4 is heated for 2 hours in an oven at 200° C. so as to form a 50 nm-70 nm oxide film 10 by thermal oxidation on the surface of wiring pattern 5 as copper re-arranged wiring.

Here, the oxide film 10 is formed on the surface of the wiring pattern 5, through thermal oxidation by heating the silicon wafer 4 for 2 hours in an oven at 200° C.; however, the formation of the oxide film is not limited to this method. For example, the heating temperature may be less or greater than 200°, or may be varied by degree. Similarly, the heating time is not limited to 2 hours, and may be less or longer than 2 hours. Further, the oxide film is not limited to one created by heat oxidation, for example, it may be formed by using chemical (liquid), such as hydrogen peroxide, or may be formed through black process for forming a cuprous oxide film, so called a black copper film.

FIG. 1(c) illustrates a photosensitive resin application step for applying a photosensitive resin 11 on the element-formed surface of the silicon wafer 4. A positive-type photosensitive resin liquid in a necessary and sufficient amount is dropped onto the silicon wafer 4, and an even liquid film of the positive-type photosensitive resin liquid is formed on the silicon wafer 4 by a spin-coater (not shown). Further, the liquid film is heated by a heating device set to 120° C. for 10 minutes to form a 10 μm thick photosensitive resin film 11.

Here, the 10 μm thick photosensitive resin film 11 is formed by dropping the positive-type photosensitive resin liquid onto the silicon wafer 4, forming an even liquid film of the positive-type photosensitive resin liquid on the silicon wafer 4 by a spin-coater (not shown), and heating the liquid film by a heating device at 120° C. for 10 minutes. However, the formation of the 10 μm thick photosensitive resin film 11 is not limited to this method. For example, the photosensitive resin film 11 may be made of a negative-type photosensitive resin liquid, and the heating temperature may be greater or less than 120°, and the heating time may be longer or less than 10 minutes. Moreover, the heating process may be omitted if the desired performance is ensured. Further, the material of the photosensitive resin film 11 is not limited to a liquid material, and may be a dry film or the like. Furthermore, instead of forming the photosensitive resin film 11, the resin material may be applied onto a printing board to be arbitrarily shaped.

FIG. 1(d) illustrates an exposure step for processing the photosensitive resin film 11 formed on the element-formed surface of the silicon wafer 4 to a desired shape. After the photosensitive resin film 11 on the silicon wafer 4 is exposed by an exposure device (not shown), followed by development by a development device (not shown), an opening 11a is formed on the photosensitive resin film 11 at the desired position to which the solder ball (described later) is to be mounted. The oxide film 10 is emerged (exposed) through the opening 11a.

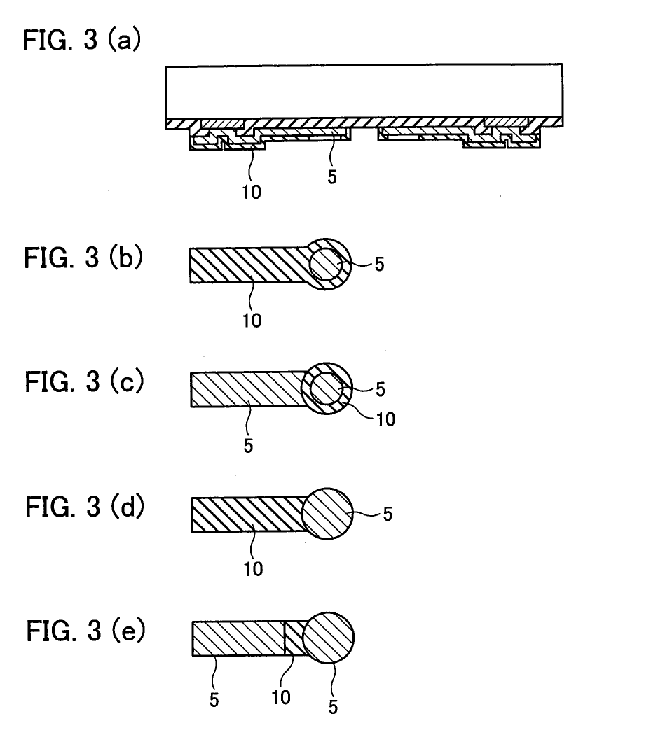

As shown in FIGS. 3(b) through 3(e), after the formation of the opening 11a, the oxide film 10 may be formed in various ways by blocking the gap between the solder ball mounting region of wiring pattern 5 and a forming region of the wiring pattern 5 (non-mounting region), more specifically, by being interposed between the mounting region and the forming region; however, the oxide film 10 is not limited to this form, as long as the film is prevented from running out (flow out) of the desired range when the solder ball 7 (described later) is melted.

In the state shown in FIG. 3(b), the oxide film 10 is formed on the solder ball non-mounting region and a ring-shaped region, that is formed on the periphery of the circular solder ball mounting region on the wiring pattern 5, connecting the non-mounting region and the ring-shaped region.

In the state shown in FIG. 3(c), the oxide film 10 is formed only on the ring-shaped region. In the shape shown in FIG. 3(d), the oxide film 10 is formed only on the non-mounting region and is not formed on the mounting region. In the state shown in FIG. 3(e), the oxide film 10 is formed on the non-mounting region of the wiring pattern 5 in contact with the mounting region, across the width of the wiring pattern 5.

FIG. 2(a) shows an oxide film removal process for removing the oxide film 10 only for the portion corresponding to the opening section 11a of the photosensitive resin 11 provided on the silicon wafer 4. The silicon wafer 4 is dipped in a dilute sulfuric acid with a concentration=10% (not shown), so that only the emerged (exposed) portion of the oxide film 10 is removed.

Here, the silicon wafer 4 is dipped in the 10% dilute sulfuric acid (not shown) to remove a part of the oxide film; however, this partial removal of the film is not limited to this way. For example, the concentration of the dilute sulfuric acid does not necessary have to be 10%, as long as not less than, for example, 5%. Further, the dipping time does not have to be 10 minutes, for example, less/greater than 10 minutes. Further, the liquid used for dipping is not limited to a dilute sulfuric acid, and may be nitric/hydrochloric acid aqueous solution, for example. Further, the removal of oxide film is not limited to etching using an agent, and may be dry etching by gas phase reaction or the like.

FIG. 2(b) shows a removal process for peeling off the photosensitive resin 11 formed on the silicon wafer 4. A liquid (not shown) containing an organic solvent and a surfactant, so called a exfoliation liquid, kept at 70° C., is prepared, and the silicon wafer is dipped in this liquid for 8 minutes to peel off/remove the photosensitive resin 11. The wafer is then washed by purified water for 10 minutes, followed by ashing for a minute at 500 W under argon atmosphere by a plasma ashing device, so as to remove the oxide film 10, which is formed in the opening during the dipping process with the peel-off liquid and the washing process by purified water.

Here, in the foregoing removal process, the exfoliation liquid containing an organic solvent and a surfactant is kept at 70° C., and the silicon wafer is dipped in this liquid for 8 minutes to peel off/remove the photosensitive resin 11, followed by washing by purified water for 10 minutes and ashing for a minute at 500 W under argon atmosphere by a plasma ashing device, so that the oxide film 10, which is deposited in the opening during the dipping process with the peel-off liquid and the washing process by purified water, is removed. However, the present invention is not limited to this way. For example, the exfoliation liquid does not necessary have to be made of an organic solvent and a surfactant, for example, it may be made of any agent enabling exfoliation of the photosensitive resin 11, for example, an alkali or the like. Further, the temperature of the exfoliation liquid is not limited to 70° C., and may be any temperature from room temperature to the boiling point of the exfoliation liquid. Similarly, the dipping time does not have to be 8 minutes, as long as the exfoliation is completed. Further, when the solder ball 7 is bonded to the wiring pattern 5 in the following reflow process, the plasma ashing after the washing is not always required. Further, the process may be carried out under other atmosphere than argon, for example, under hydrogen, or under reduction atmosphere using hydrogen or the like.

FIG. 2(c) shows a solder ball preparation step for preparing a solder ball 7 on which a flux 9 is transferred, and FIG. 2(d) shows a solder ball placing step for placing the solder ball 7, on which the flux 9 is transferred, to an desired position on the wiring pattern 5 of the silicon wafer 4, after the oxide film 10 has been removed from the portion. This step is performed by a solder ball mounting device. First, a solder ball 7 on which a desired amount of flux 9 is transferred by a solder ball mounting device is prepared. Then, the solder ball 7 is placed in the desired portion of the wiring pattern 5, from which the oxide film 10 has been removed, by the solder ball mounting device, using the tackiness (adherence) of the flux 9. More specifically, the solder ball 7 is mounted onto the mounting region by an adhesion flux 9a, that is obtained by deforming the flux 9 so that the flux 9 is adhered to the wiring pattern 5 through which the flux 9 is exposed.

Here, the solder ball 7 on which a desired amount of flux 9 is transferred by a solder ball mounting device is prepared, and the solder ball 7 is placed in the desired portion of the wiring pattern 5, from which the oxide film 10 has been removed, by the solder ball mounting device, using the tackiness (adherence) of the flux 9. However, the method of mounting solder ball is not limited to this way. For example, the flux 9 does not have to be transferred onto the solder ball 7 in advance, and instead, the flux 9 may be transferred onto the desired region (mounting region) of the wiring pattern 5, from which the oxide film 10 is removed, by a transfer pin or the like provided in the solder ball mounting device, and the solder ball 7 may be mounted/adhered onto the desired region on which the flux is transferred.

FIG. 2(e) shows a bonding process for bonding the solder ball 7 to the wiring pattern 5 by heating the silicon wafer 4, on which the solder ball 7 is placed, in a reflow oven, followed by cooling. The silicon wafer 4 is placed in a reflow oven to melt the solder ball 7, and the solder ball is then cooled down and is solidified so that the solder ball 7 is bonded to the wiring pattern 5.

Here, the silicon wafer 4 is placed in a reflow oven to melt the solder ball 7, and the solder ball is then cooled down and is solidified so that the solder ball 7 is bonded to the wiring pattern 5. However, the bonding process is not limited to this way. For example, the temperature may be changed within a temperature range enabling the solder ball 7 to be melted and moved.

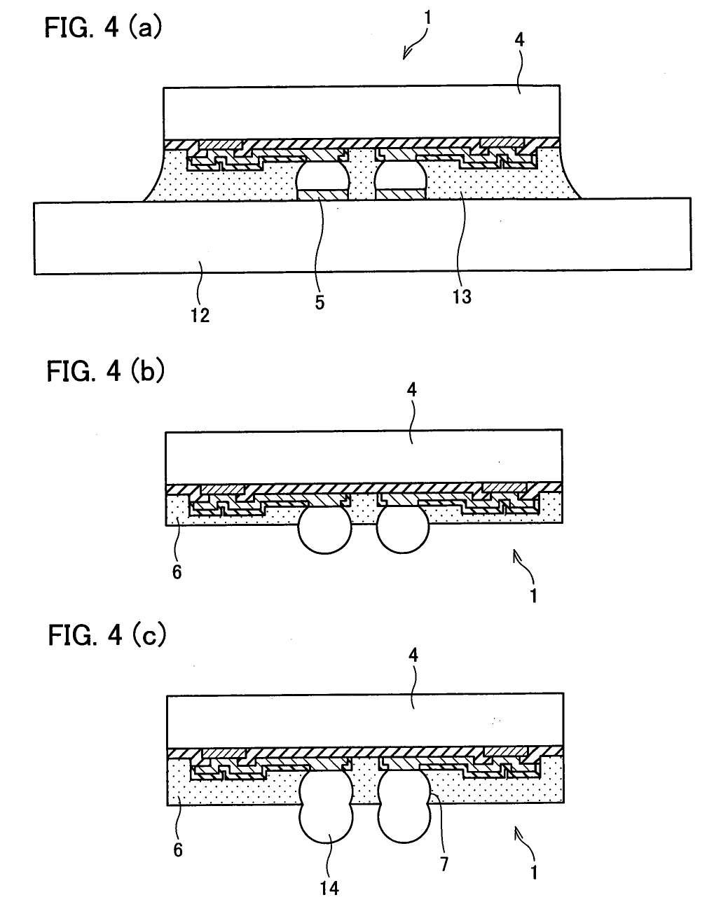

20 The silicon wafer 4 including a plurality of CSP structure semiconductor chips is divided into individual pieces of semiconductor chip 1 by a dicing device. Then, as shown in FIG. 4(a), the semiconductor chip 1 is adhered to a substrate 12 via the solder ball 7 using a reflow oven. Here, to protect the wiring pattern 5 of the substrate 12 and to improve adhesion strength, an underfill material 13 may be injected between the semiconductor chip 1 and the substrate 12.

Further, the division into the individual semiconductor chips 1 may be otherwise carried out as follows. After the bonding process, an appropriate amount of resin liquid sealing material is dropped onto an desired portion(s), avoiding the solder ball 7, on the surface of the semiconductor chip, and the resin is naturally flattened with its flowability, or is flattened by a spin-coater to be an even film, and is cured by any available methods such as thermal curing or the like, so that a sealing resin 6 is obtained. The wafer (not shown) including the plurality of CSP structure semiconductor chips is then divided into individual pieces of semiconductor chip 1. In this manner, as shown in FIG. 4(b), each exposed region, that is, a protection film 3, an oxide film 10 etc. is covered by the sealing resin 6, thereby obtaining a CSP structure semiconductor chip in which a part of the solder ball is exposed through the surface of the sealing resin 6.

Further, FIG. 4(c) shows an example of employing the silicon wafer to a conventional method (Japanese Laid-Open Patent application Tokukaihei 09-213830, published on Aug. 15, 1997). The publication (Tokukaihei 09-213830) claims priority based on a US patent application, with a Priority No 592008.

In the conventional art above, after the bonding process, the wiring-pattern-provided side of the silicon wafer 4 is sealed by covering a part or the whole of the solder ball 7, and the sealing resin 6 is then cured, and polished to partially expose the buried solder ball 7, so that the polished surface of the sealing resin 6 and the polished surface of the solder ball 7 form a continuous plane.

Another solder ball 14 with a lower boiling point than the solder ball 7 is prepared, and an desired amount of flux (not shown) is transferred onto the solder ball 14 by a solder ball mounting device (not shown). Then, with the solder ball mounting device, the solder ball 14 is placed on the polished surface of the solder ball 7 by tackiness of the flux.

Here, another solder ball 14 with a lower boiling point than the solder ball 7, on which an desired amount of flux (not shown) is transferred, is prepared using a solder ball mounting device (not shown); and the solder ball 14 is placed on the polished surface of the solder ball 7 by tackiness of the flux. However, this may be replaced with other method, for example, the flux does not have to be transferred onto the new solder ball 14 with a lower boiling point, and may be transferred onto the polished surface of the solder ball 7 by a flux transfer pin or the like (not shown) provided in the solder ball mounting device, allowing the solder ball 14 to be placed on the desired region where the flux has been transferred.

Next, the silicon wafer 4 is placed in a reflow oven set to 245° C. to melt the solder ball 14 with a lower boiling point, followed by cooling, so that the solder ball 14 is cured and bonded to the polished solder ball 7, thus creating an external electrode terminal. Here, the silicon wafer 4 is placed in a reflow oven at 245° C., to melt only the solder ball 14 with a lower boiling point, followed by cooling, so that the solder ball 14 is cured and bonded to the polished solder ball 7. However, this process may be performed in other ways, for example, the temperature is not limited to 245° C., and may be any temperature at which the solder ball 14 is melted and moved but the solder ball 7 is not melted.

[Second Embodiment]

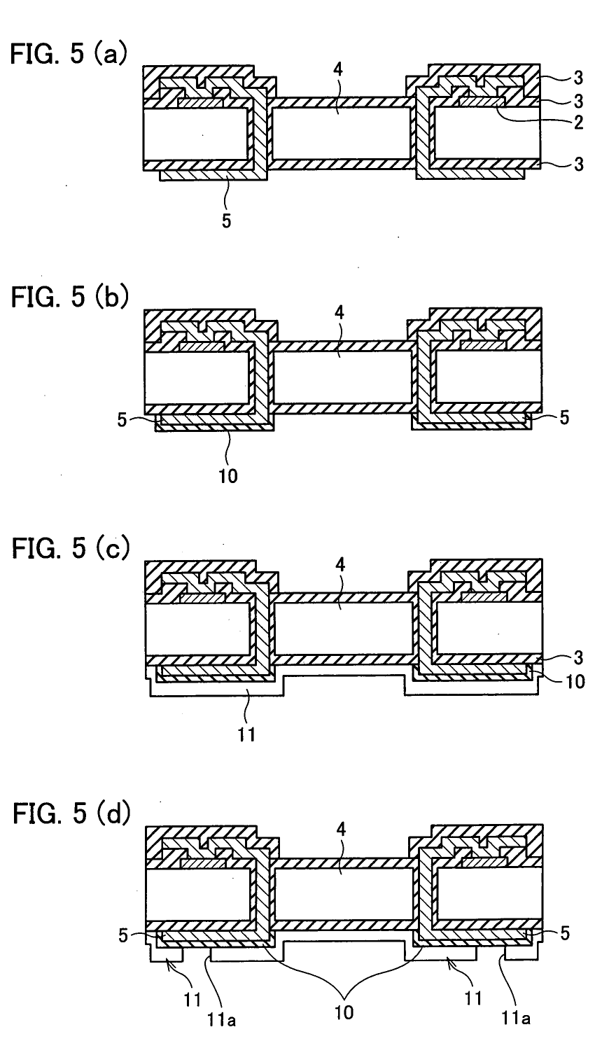

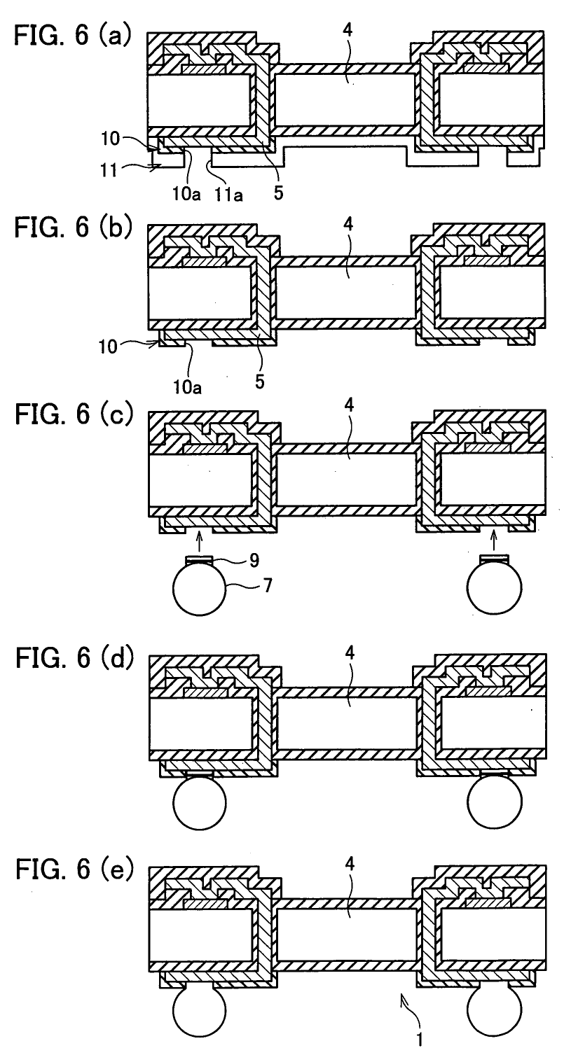

FIGS. 5(a) through 6(e) are cross-sectional views illustrating some of the processing steps of a manufacturing method of semiconductor device according to Second Embodiment of the present invention. These figures each show a cross section in manufacturing of one of plural semiconductor chips formed on a silicon wafer 4. The following explains the manufacturing method according to Second Embodiment of the present invention with reference to FIGS. 5(a) through 6(e).

FIG. 5(a) shows a silicon wafer 4 on which an electric circuit element, such as an integrated circuit, and electrode pads for allowing external electrical conduction of the electric circuit are formed through an electric circuit forming step (not shown). The silicon wafer 4 further includes a protection film 3 with an opening on a desired one of the electrode pads 2 through a protection film forming step (not shown). Further, a wiring pattern 5 as copper re-wiring is formed across the silicon wafer 4 from the element (electric circuit)-provided surface to the rear surface while being electrically connected via the electrode pad 2. The wiring pattern5 is formed through a wiring forming step (not shown). In this example, the wiring pattern 5 is the copper re-wiring electrically connected to the electrode pad 2, formed through a wiring forming step; however, the copper re-wiring may instead be other re-wiring made of a nickel or other metals, including an alloy.

FIG. 1(b) shows an oxide film forming step for forming an oxide film 10 on the surface of wiring pattern 5, formed on the rear surface of element-formed surface of the silicon wafer 4. The silicon wafer 4 is heated for 2 hours in an oven at 200° C. so as to form an oxide film 10 by thermal oxidation on the surface of wiring pattern 5 as copper re-arranged wiring. Here, the oxide film 10 is formed on the surface of the copper wiring pattern 5, through thermal oxidation by heating the silicon wafer 4 for 2 hours in an oven at 200° C.; however, the formation of the oxide film is not limited to this method. For example, the heating temperature may be less or greater than 200°, or may be varied by degree. Similarly, the heating time is not limited to 2 hours, and may be less or longer than 2 hours. Further, the oxide film is not limited to one created by heat oxidation, for example, it may be formed by using medicine (liquid), such as hydrogen peroxide, or may be formed through black process for forming a cuprous oxide film, so called a black copper film

FIG. 5(c) illustrates a photosensitive resin application step for applying a photosensitive resin 11 on the opposite surface of the element-formed surface of the silicon wafer 4. A positive-type photosensitive resin liquid in a necessary and sufficient amount is dropped onto the silicon wafer 4, and an even liquid film of the positive-type photosensitive resin liquid is formed on the rear surface of silicon wafer 4 by a spin-coater (not shown). Further, the liquid film is heated by a heating device set to 120° C. for 10 minutes to form a 10 μm thick photosensitive resin film 11.

Here, the 10 μm thick photosensitive resin film 11 is formed on the surface opposite to the element-formed surface, by dropping the positive-type photosensitive resin liquid onto the silicon wafer 4, forming an even liquid film of the positive-type photosensitive resin liquid on the silicon wafer 4 by a spin-coater (not shown), and heating the liquid film by a heating device at 120° C. for 10 minutes. However, the formation of the 10 μm thick photosensitive resin film 11 is not limited to this method. For example, the photosensitive resin film 11 may be made of a negative-type photosensitive resin liquid, and the heating temperature may be greater or less than 120°, and the heating time may be longer or less than 10 minutes. Moreover, the heating process may be omitted if the desired performance is ensured. Further, the material of the photosensitive resin film 11 is not limited to a liquid material, and may be a dry film or the like. Furthermore, instead of forming the photosensitive resin film 11, the resin material may be applied onto a printing board to be arbitrarily shaped.

FIG. 5(d) illustrates an exposure step for processing the photosensitive resin film 11 formed on the rear surface of the silicon wafer 4 to a desired shape. After the photosensitive resin film 11 on the silicon wafer 4 is exposed by an exposure device (not shown), followed by development by a development device (not shown), an opening 11 is formed on the photosensitive resin film 11 at the desired position to which the solder ball (described later) is to be mounted. The oxide film 10 is emerged (exposed) through the opening 11a. As shown in FIGS. 3(b) through 3(e), after the formation of the opening 11a, the oxide film 10 may be formed in various ways by blocking the gap between the solder ball mounting region of wiring pattern 5 and a forming region of the wiring pattern 5 (non-mounting region), more specifically, by being interposed between the mounting region and the forming region; however, the oxide film 10 is not limited to this form, as long as the film is prevented from running out (flow out) of the desired range when the solder ball 7 (described later) is melted.

FIG. 6(a) shows an oxide film removal process for removing only the oxide film 10 only for the portion corresponding to the opening section 11a of the photosensitive resin 11 provided on the silicon wafer 4. The silicon wafer 4 is dipped in a dilute sulfuric acid with a concentration=10% (not shown), so that only the emerged (exposed) portion of the oxide film 10 is removed. An oxide film opening 10a is thus formed, so that the wiring pattern 5 is exposed, only for the portion corresponding to the area where the oxide film 10 is removed.

Here, the silicon wafer 4 is dipped in the 10% dilute sulfuric acid (not shown) to remove a part of the oxide film; however, this partial removal of the film is not limited to this way. For example, the concentration of the dilute sulfuric acid does not necessary have to be 10%, as long as not less than, for example, 5%. Further, the dipping time does not have to be 10 minutes, for example, less/greater than 10 minutes. Further, the liquid used for dipping is not limited to a dilute sulfuric acid, and may be nitric/hydrochloric acid aqueous solution, for example. Further, the removal of oxide film is not limited to etching using an agent, and may be dry etching by gas phase reaction or the like.

FIG. 6(b) shows a removal process for peeling off the photosensitive resin 11 formed on the silicon wafer 4. A liquid (not shown) containing an organic solvent and a surfactant, so called a exfoliation liquid, kept at 70° C., is prepared, and the silicon wafer is dipped in this liquid for 8 minutes to peel off/remove the photosensitive resin 11. The wafer is then washed by purified water for 10 minutes, followed by ashing for a minute at 500 W under argon atmosphere by a plasma ashing device, so as to remove the oxide film 10, which is deposited in the opening during the dipping process with the peel-off liquid and the washing process by purified water.

Here, in the foregoing removal process, the exfoliation liquid containing an organic solvent and a surfactant is kept at 70° C., and the silicon wafer is dipped in this liquid for 8 minutes to peel off/remove the photosensitive resin 11, followed by washing by purified water for 10 minutes and ashing for a minute at 500 W under argon atmosphere by a plasma ashing device, so that the oxide film 10, which is deposited in the opening during the dipping process with the peel-off liquid and the washing process by purified water, is removed. However, the present invention is not limited to this way. For example, the exfoliation liquid does not necessary have to be made of an organic solvent and a surfactant, for example, it may be made of any agent enabling exfoliation of the photosensitive resin 11, for example, an alkali or the like. Further, the temperature of the exfoliation liquid is not limited to 70° C., and may be any temperature from room temperature to the boiling point of the exfoliation liquid. Similarly, the dipping time does not have to be 8 minutes, as long as the exfoliation is completed. Further, when the solder ball 7 is bonded to the wiring pattern 5 in the following reflow process, the plasma ashing after the washing is not always required. Further, the process may be carried out under other atmosphere than argon, for example, under hydrogen, or under reduction atmosphere using hydrogen or the like.

FIG. 6(c) shows a solder ball preparation step for preparing a solder ball 7 on which a flux 9 is transferred, and FIG. 2(d) shows a solder ball placing step for placing the solder ball 7, on which the flux 9 is transferred, to an desired position on the wiring pattern 5 of the silicon wafer 4, after the oxide film 10 has been removed from the portion. This step is performed by a solder ball mounting device. First, a solder ball 7 on which a desired amount of flux 9 is transferred by a solder ball mounting device is prepared. Then, the solder ball 7 is placed in the desired portion of the wiring pattern 5, from which the oxide film 10 has been removed, by the solder ball mounting device, using the tackiness (adherence) of the flux 9. More specifically, the solder ball 7 is mounted onto the mounting region by an adhesion flux 9a, that is obtained by deforming the flux 9 so that the flux 9 is adhered to the wiring pattern 5 through which the flux 9 is exposed.

Here, the solder ball 7 on which a desired amount of flux 9 is transferred by a solder ball mounting device is prepared, and the solder ball 7 is placed in the desired portion of the wiring pattern 5, from which the oxide film 10 has been removed, by the solder ball mounting device, using the tackiness (adherence) of the flux 9. However, the method of mounting solder ball is not limited to this way. For example, the flux 9 does not have to be transferred onto the solder ball 7 in advance, and instead, the flux 9 may be transferred onto the desired region of the wiring pattern 5, from which the oxide film 10 is removed, by a transfer pin or the like provided in the solder ball mounting device, allowing the solder ball 7 to be placed onto the desired region on which the flux is transferred.

FIG. 2(e) shows a bonding process for bonding the solder ball 7 to the wiring pattern 5 by heating the silicon wafer 4, on which the solder ball 7 is placed, in a reflow oven, followed by cooling. The silicon wafer 4 is placed in a reflow oven to melt the solder ball 7, and the solder ball is then cooled down and is solidified so that the solder ball 7 is bonded to the wiring pattern 5, thereby obtaining a CSP structure semiconductor chip 1.

Here, the silicon wafer 4 is placed in a reflow oven to melt the solder ball 7, and the solder ball is then cooled down and is solidified so that the solder ball 7 is bonded to the wiring pattern 5. However, the bonding process is not limited to this way. For example, the temperature may be changed within a temperature range enabling the solder ball 7 to be melted and moved.

[Third Embodiment]

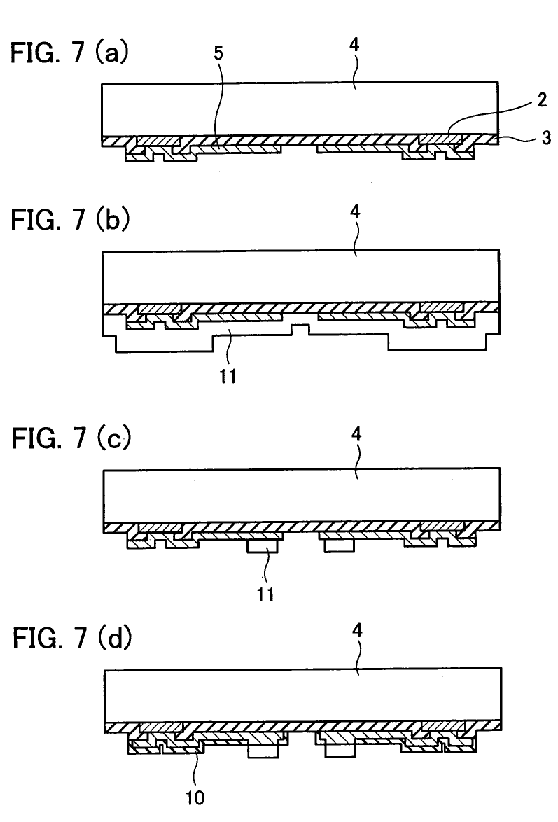

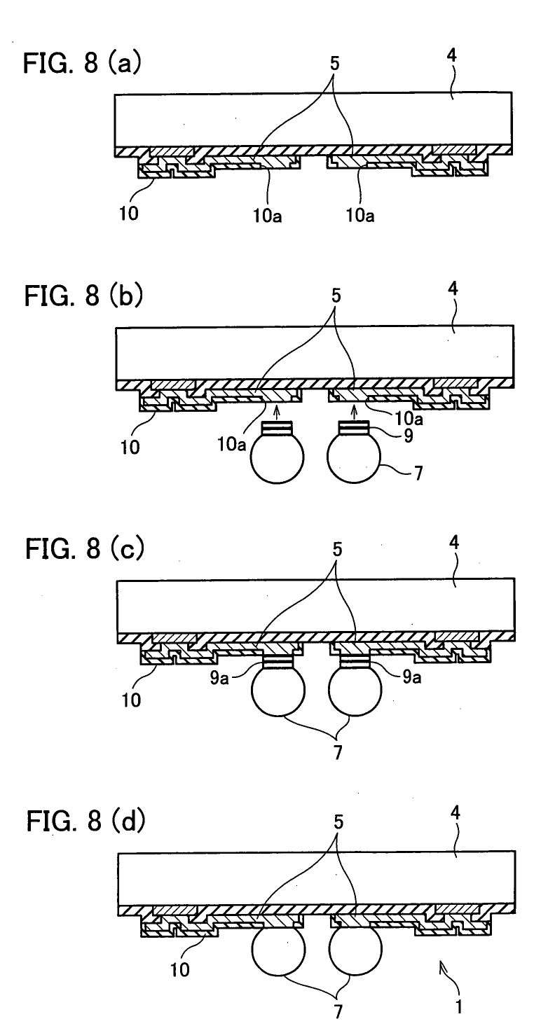

FIGS. 7(a) through 8(d) are cross-sectional views illustrating a semiconductor device and a manufacturing method thereof according to Third Embodiment of the present invention. These figures each show a cross section of one of plural semiconductor chips 1 formed on a silicon wafer 4. The following explains the manufacturing method according to Third Embodiment of the present invention with reference to FIGS. 7(a) through 8(d).

FIG. 1(a) shows a silicon wafer 4 on which an electric circuit, such as an integrated circuit, and electrode pads for allowing external electrical conduction of the electric circuit are formed through an electric circuit forming step (not shown). The silicon wafer 4 further includes a protection film 3 with an opening on a desired one of the electrode pads 2 through a protection film forming step (not shown). The silicon wafer 4 further includes a wiring pattern 5 as copper re-wiring that is electrically conducted and formed on the electrode pad 2; however, the copper re-wiring may instead be other re-wiring made of a nickel or other metals, including an alloy.

FIG. 7(b) illustrates a photosensitive resin application step for applying a photosensitive resin 11 formed on the surface of the wiring pattern 5 formed on the element-formed surface of the silicon wafer 4. A positive-type photosensitive resin liquid in a necessary and sufficient amount is dropped onto the silicon wafer 4, and an even liquid film of the positive-type photosensitive resin liquid is formed on the silicon wafer 4 by a spin-coater (not shown). Further, the liquid film is heated by a heating device set to 120° C. for 10 minutes to form a film of 10 μm thick photosensitive resin 11.

Here, the 10 μm thick photosensitive resin film 11 is formed by dropping the positive-type photosensitive resin liquid onto the silicon wafer 4, forming an even liquid film of the positive-type photosensitive resin liquid on the silicon wafer 4 by a spin-coater (not shown), and heating the liquid film by a heating device at 120° C. for 10 minutes. However, the formation of the 10 μm thick photosensitive resin film 11 is not limited to this method. For example, the photosensitive resin film 11 may be made of a negative-type photosensitive resin liquid, and the heating temperature may be greater or less than 120°, and the heating time may be longer or less than 10 minutes. Moreover, the heating process may be omitted if the desired performance is ensured. Further, the material of the photosensitive resin film 11 is not limited to a liquid material, and may be a dry film or the like. Furthermore, instead of forming the photosensitive resin film 11, the resin material may be applied onto a printing board to be arbitrarily shaped.

FIG. 1(c) illustrates an exposure step for processing the photosensitive resin film 11 formed on the element-formed surface of the silicon wafer 4 to a desired shape. After the photosensitive resin film 11 on the silicon wafer 4 is exposed by an exposure device (not shown), followed by development by a development device (not shown), an opening is formed on the photosensitive resin film 11 with respect to the whole area excluding the desired position to which the solder ball 7 is to be mounted (that is, the opening is formed on the non-mounting region). The wiring pattern 5 is emerged (exposed) through this opening.

FIG. 1(b) shows an oxide film forming step for forming an oxide film 10 on the surface of wiring pattern 5, formed as re-arranged wiring on the element-formed surface of the silicon wafer 4. The silicon wafer 4 is heated for 2 hours in an oven at 200° C. so as to form an oxide film 10 by thermal oxidation on the surface of wiring pattern 5 as copper re-arranged wiring.

Here, the oxide film 10 is formed on the surface of the wiring pattern 5, through thermal oxidation by heating the silicon wafer 4 for 2 hours in an oven at 200° C.; however, the formation of the oxide film is not limited to this method. For example, the heating temperature may be less or greater than 200°, or may be varied by degree. Similarly, the heating time is not limited to 2 hours, and may be less or longer than 2 hours. Further, the oxide film is not limited to one created by heat oxidation, for example, it may be formed by using medicine (liquid), such as hydrogen peroxide, or may be formed through black process for forming a cuprous oxide film, so called a black copper film.

FIG. 8(a) shows a removal process for peeling off the photosensitive resin 11 formed on the silicon wafer 4. A liquid (not shown) containing an organic solvent and a surfactant, so called a exfoliation liquid, kept at 70° C., is prepared, and the silicon wafer is dipped in this liquid for 8 minutes to peel off/remove the photosensitive resin 11. The wafer is then washed by purified water for 10 minutes, followed by ashing for a minute at 500 W under argon atmosphere by a plasma ashing device, so as to remove the residual photosensitive resin 11 from the desired portion where the solder ball is to be mounted. As a result, the surface of the oxide film 10 and the exposed surface of the wiring pattern 5 form a continuous plane (one plane).

Here, in the foregoing removal process, the exfoliation liquid containing an organic solvent and a surfactant is kept at 70° C., and the silicon wafer is dipped in this liquid for 8 minutes to peel off/remove the photosensitive resin 11, followed by washing by purified water for 10 minutes and ashing for a minute at 500 W under argon atmosphere by a plasma ashing device, so as to remove the residual photosensitive resin 11 from the desired portion where the solder ball is to be mounted. However, the present invention is not limited to this way. For example, the exfoliation liquid does not necessary have to be made of an organic solvent and a surfactant, for example, it may be made of any agent enabling exfoliation of the photosensitive resin 11, for example, an alkali or the like. Further, the temperature of the exfoliation liquid is not limited to 70° C., and may be any temperature from room temperature to the boiling point of the exfoliation liquid. Similarly, the dipping time does not have to be 8 minutes, as long as the exfoliation is completed.

Further, when the solder ball 7 is bonded to the wiring pattern 5 in the following reflow process, the plasma ashing after the washing is not always required. Further, the process may be carried out under other atmosphere than argon, for example, under hydrogen.

FIGS. 3(b) through 3(e) show the possible states of the oxide film 10 and the wiring pattern 5 as a result of the exfoliation; however, their states are not limited to these forms, and may be in other forms as long as the film is prevented from running out (flow out) of the desired range when the solder ball 7 (described later) is melted.

FIG. 8(b) shows a solder ball preparation step for preparing a solder ball 7 on which a flux 9 is transferred, and FIG. 8(c) shows a solder ball placing step for placing the solder ball 7, on which the flux 9 is transferred, to an desired position on the wiring pattern 5 of the silicon wafer 4, after the oxide film 10 has been removed from the portion. This step is performed by a solder ball mounting device. First, a solder ball 7 on which a desired amount of flux 9 is transferred by a solder ball mounting device is prepared. Then, the solder ball 7 is placed in the desired portion of the wiring pattern 5, from which the oxide film 10 has been removed, by the solder ball mounting device, with the adhesion flux 9a using the tackiness of the flux 9.

Here, the solder ball 7 on which a desired amount of flux 9 is transferred by a solder ball mounting device is prepared, and the solder ball 7 is placed in the desired portion of the wiring pattern 5, from which the oxide film 10 has been removed, by the solder ball mounting device, using the tackiness (adherence) of the flux 9. However, the method of mounting solder ball is not limited to this way. For example, the flux 9 does not have to be transferred onto the solder ball 7 in advance, and instead, the flux 9 may be transferred onto the desired region of the wiring pattern 5, from which the oxide film 10 is removed, by a transfer pin or the like provided in the solder ball mounting device, and the solder ball 7 may be placed onto the desired region on which the flux is transferred.

FIG. 2(e) shows a bonding process for bonding the solder ball 7 to the wiring pattern 5 by heating the silicon wafer 4, on which the solder ball 7 is placed, in a reflow oven, followed by cooling. The silicon wafer 4 is placed in a reflow oven to melt the solder ball 7, and the solder ball is then cooled down and is solidified so that the solder ball 7 is bonded to the wiring pattern 5.

Here, the silicon wafer 4 is placed in a reflow oven to melt the solder ball 7, and the solder ball is then cooled down and is solidified so that the solder ball 7 is bonded to the wiring pattern 5. However, the bonding process is not limited to this way. For example, the temperature may be changed within a temperature range enabling the solder ball 7 to be melted and moved.

The silicon wafer 4 including a plurality of CSP structure semiconductor chips is divided into individual pieces of semiconductor chip 1 by a dicing device. Then, as shown in FIG. 4(a), the semiconductor chip 1 is adhered to a substrate 12 via the solder ball 7 using a reflow oven. Here, to protect the wiring pattern 5 of the substrate 12 and to improve adhesion strength, an underfill material 13 may be injected between the semiconductor chip 1 and the substrate 12, as shown in FIG. 4(a).

Further, the division into the individual semiconductor chips 1 may be otherwise carried out as follows. After the bonding process, an appropriate amount of resin liquid sealing material is dropped onto an desired portion(s), avoiding the solder ball 7, on the surface of the semiconductor chip, and the resin is naturally flattened with its flowability, or is flattened by a spin-coater to be an even film, and is cured by any available methods such as thermal curing or the like, so that a sealing resin 6 is obtained. The wafer (not shown) including the plurality of CSP structure semiconductor chips is then divided into individual pieces of semiconductor chip 1. In this manner, as shown in FIG. 4(b), a CSP structure semiconductor chip 1 is obtained.

Further, FIG. 4(c) shows an example of employing the silicon wafer to a conventional method (Japanese Laid-Open Patent application Tokukaihei 09-213830, published on Aug. 15, 1997). The publication (Tokukaihei 09-213830) claims priority based on a US patent application, with a Priority No 592008. In the conventional art above, after the bonding process, the wiring-pattern-provided side of the silicon wafer 4 is sealed by covering a part or the whole of the solder ball 7, and the sealing resin 6 is then cured, and polished to partially expose the buried solder ball 7, so that the polished surface of the sealing resin 6 and the polished surface of the solder ball 7 form a continuous plane.

Another solder ball 14 with a lower boiling point than the solder ball 7 is prepared, and an desired amount of flux (not shown) is transferred onto the solder ball 14 by a solder ball mounting device (not shown). Then, with the solder ball mounting device, the solder ball 14 is placed on the polished surface of the solder ball 7 by tackiness of the flux.

Here, another solder ball 14 with a lower boiling point than the solder ball 7, on which an desired amount of flux (not shown) is transferred, is prepared using a solder ball mounting device (not shown); and the solder ball 14 is placed on the polished surface of the solder ball 7 by tackiness of the flux. However, this may be replaced with other method, for example, the flux does not have to be transferred onto the new solder ball 14 with a lower boiling point, and may be transferred onto the polished surface of the solder ball 7 by a flux transfer pin or the like (not shown) provided in the solder ball mounting device, allowing the solder ball 14 to be placed on an desired region where the flux has been transferred.

Next, the silicon wafer 4 is placed in a reflow oven set to 245° C. to melt the solder ball 14 with a lower boiling point, followed by cooling, so that the solder ball 14 is cured and bonded to the polished solder ball 7, thus creating an external electrode terminal. Here, the silicon wafer 4 is placed in a reflow oven at 245° C., to melt only the solder ball 14 with a lower boiling point, followed by cooling, so that the solder ball 14 is cured and bonded to the polished solder ball 7. However, this process may be performed in other ways, for example, the temperature is not limited to 245° C., and may be any temperature at which the solder ball 14 is melted and moved but the solder ball 7 is not melted.

[Fourth Embodiment]

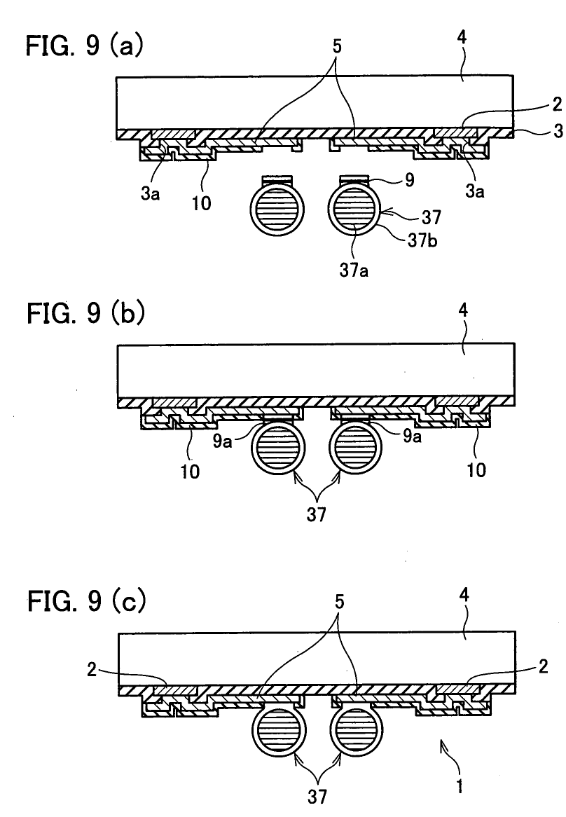

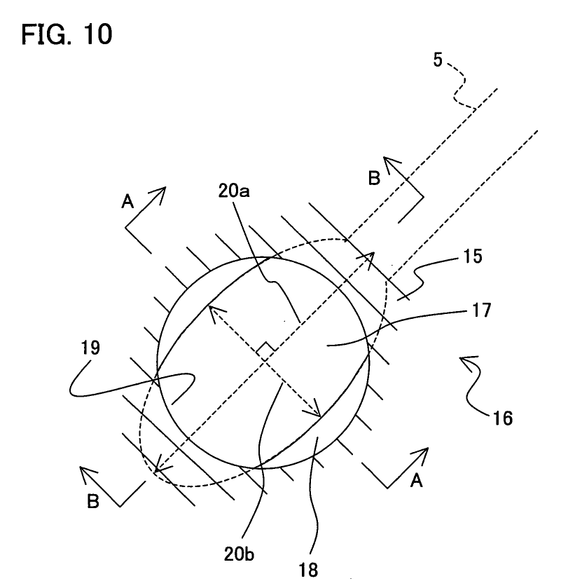

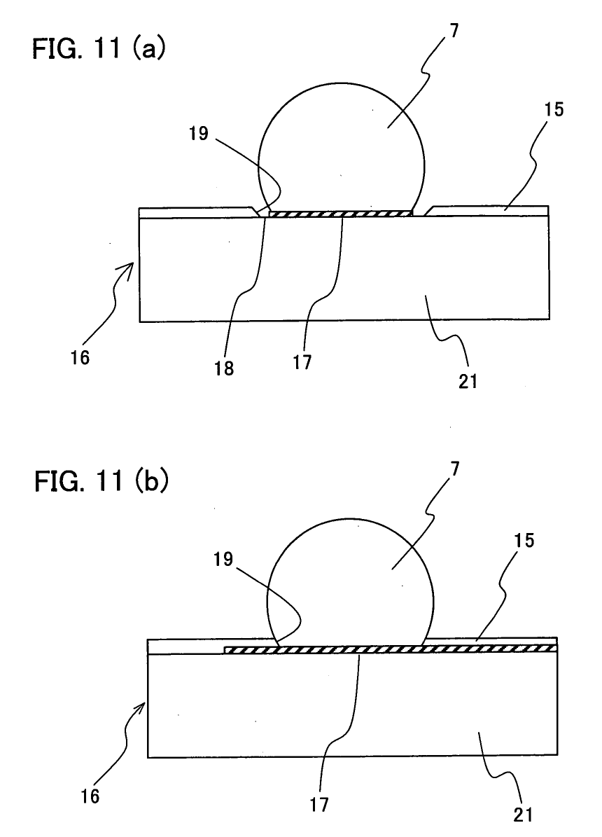

FIGS. 9(a) through 9(c) are cross-sectional views illustrating a semiconductor chip (semiconductor device) 1 and a manufacturing method thereof according to Fourth Embodiment of the present invention. These figures each show a cross section in manufacturing of one of plural semiconductor chips formed on a silicon wafer (substrate) 4. The following explains the semiconductor chip 1 and the manufacturing method thereof according to Fourth Embodiment of the present invention with reference to FIGS. 9(a) through 9(c).

In Fourth Embodiment of the present invention, as shown in FIGS. 9(a) through 9(c), the solder ball 7 used in First through Third embodiments is replaced with a solder ball 37 made up of a main ball 37a, that is substantially round, and a solder film 37b as an external skin for coating the main ball 37a.

The material of the main ball 37a may be a thermo-resistant resin at least not dissolving a temperature around the fusing point of the solder film 37b; otherwise, material may be copper, copper alloy, or any conductive metals.

Use of resin makes the main ball light-weighted, improving the adhesion of the solder ball 37 by the tackiness, thereby ensuring secure forming of the external electrode terminal. In contrast, when the main ball 37a is made of copper or copper alloy, the created external electrode terminal will have superior electric conductivity.

When the foregoing bonding process is performed with the solder ball 37 including a main ball 37a made of copper or copper alloy, the process is preferably carried out such that the silicon wafer 4 is placed in a nitrogen reflow oven to melt the solder ball 7 by setting the temperature so that the surface of the wafer 4 is heated up to 260° C., and the solder ball 37 is then cooled down and solidified, adhering to the wiring pattern 5. Here, the silicon wafer 4 is placed in a nitrogen reflow oven to melt the solder ball 37 by setting the temperature so that the surface of the wafer 4 is heated up to 260° C., and the solder ball is then cooled down and solidified, and is bonded to the wiring pattern 5. However, the bonding process is not limited to this way. For example, the temperature may be changed from 260° C. within a temperature range enabling the solder ball 7 to be melted and moved.

A manufacturing method of the present invention may also be expressed as a method comprising: a protection film forming step for forming a protection film 3 with an opening, on an electrode pad 2; an oxide film forming step for forming an oxide film 10 on the surface of a wiring pattern formed on an element-formed surface of a silicon wafer 4, which wiring pattern is copper wiring pattern, that is conducted through the electrode pad 2 through a wiring forming step; a photosensitive resin applying step for applying the photosensitive resin 11 on the element-formed surface of the silicon wafer 4; an exposure step for carrying out exposure for the photosensitive resin 11 formed on the element-formed surface of the silicon wafer 4 so as to process the resin 11 to an desired shape; an oxide film removal process for removing the oxide film only for the portion corresponding to the opening of the photosensitive resin 11 on the silicon wafer 4; an exfoliation process for peeling off the photosensitive resin 1.1 formed on the silicon wafer 4; a solder ball preparation process for preparing a solder ball 7 on which a flux 9 is transferred; a solder ball disposition process for disposing by a solder ball mounting device the solder ball 7 on which the flux 9 is transferred, to an desired position on the wiring pattern 5 of the silicon wafer 4, after the oxide film 10 has been removed from the portion; a bonding process for bonding the solder ball 7 to the wiring pattern 5 by heating the silicon wafer. 4, on which the solder ball 7 is placed, in a reflow oven, followed by cooling.

In this manner, through the respective processes, the melted external electrode terminal is prevented from spreading out of the desired range of the wiring pattern 5, that is bonded to the solder ball 7.

Alternately, a manufacturing method of the present invention may also be expressed as a method comprising: a protection film forming step for forming a protection film 3 with an opening, on an electrode pad 2; a photosensitive resin forming step for forming a photosensitive resin 11 on the surface of a wiring pattern formed on an element-formed surface of a silicon wafer 4, which wiring pattern is copper wiring pattern, that is conducted through the electrode pad 2 through a wiring forming step; an exposure step for carrying out exposure for the photosensitive resin 11 formed on the element-formed surface of the silicon wafer 4 so as to process the resin 11 to an desired shape; an oxide film forming step for forming an oxide film 10 on the surface of the wiring pattern formed on the element-formed surface of the silicon wafer 4; an exfoliation process for peeling off the photosensitive resin 11 formed on the silicon wafer 4; a solder ball preparation process for preparing a solder ball 7 on which a flux 9 is transferred; a solder ball disposition process for disposing by a solder ball mounting device the solder ball 7 on which the flux 9 is transferred, to an desired position on the wiring pattern 5 of the silicon wafer 4, after the oxide film 10 has been removed from the portion; a bonding process for bonding the solder ball 7 to the wiring pattern 5 by heating the silicon wafer 4, on which the solder ball 7 is placed, in a reflow oven, followed by cooling.

In this manner, through the respective processes, the melted external electrode terminal is prevented from spreading out of the desired range of the wiring pattern 5, that is bonded to the solder ball 7.

Accordingly, due to the poor wettability of the melted solder to the oxide film 10, the melted solder with greater flowability is prevented from flowing out of the desired range of the wiring pattern 5 even without a solder resist, thereby preventing generation of a solder bridge in a CSP structure semiconductor device. Therefore, expansion, exfoliation, cracks of the solder resist does not occur in the present invention, allowing omission of a high temperature process for curing the solder resist. On this account, the present invention provides a semiconductor device and manufacturing method thereof not causing a decrease of reliability on the solder resist and/or the boundaries of the solder resist due to stress or moisture absorption after mounting to the printed board. Further, since the solder resist process is omitted, the present invention provides a semiconductor device and manufacturing method thereof at lower cost.

The following more specifically explains wettability of the solder and the oxide film 10. Wettability can be easily defined in reference to the contact angle; however, “Spread Test (JIS Z 3197)” or “Meniscograph Test (JIS C 0053)” is used to measure the wettability itself.

In the “Spread Test”, the height of the solder is measured before (D) and after (H) being melted, and the difference (D−H) is divided by D, and the resulting value is multiplied by 100, thus obtaining a Spread rate (%).

In “Meniscograph Test”, a sample piece (in this example, copper or copper with an oxidized surface) is vertically dipped into a tank filled with melted solder, and a force applied to the sample piece is measured. In combination of solder and the sample piece with a poor wettability to the solder, an upward force (a force of pushing back the piece) is applied to the sample piece; in contrast, in combination of solder and the sample piece with a good wettability to the solder, an downward force (a force of pulling the piece into the solder due to the solder risen along the sample piece, which causes surface tension, thus decreasing superficial area) is immediately applied to the sample piece. Generally, by changing the combination of the melted solder and the sample piece, the applied force changes from upward to downward. Here, by plotting the time and the force as X-axis and Y-axis, respectively, the process in which the melted solder is gradually wet can be numerically observed. The time taken to change the upward force into downward (until the force becomes 0(N)) after the dipping is called “Wetting Time”, and the downward force is called “Wetting Force”.

The difference in Spread Rate cannot be specified, as various fluxes are used for removal or prevention of surface oxide film in actual solder bonding. However, according to “Spread Test”, the difference in Spread Rate before and after oxidization of Cu is several %. On the other hand, according to “Meniscograph Test”, when the oxide film does not exist on the surface, the Wetting Time is less than 1 second, and when an oxide film exists, the time taken to remove the oxide film by the flux is usually approximately 1 second in the case of a 10 nm oxide film, based on one result of the test.

Generally, an oxide film layer formed on the copper surface of the wiring pattern 5 by natural oxidization has a thickness=several nms. In the foregoing embodiments, the heating process is performed at 200° C. for 2 hours, and this presumably produces an oxide film=50 nm or more, according to the fact that a heating process performed at 150° C. for 2 hours creates a 50 nm oxide film. On this account, “Wetting Time” for the area provided with the oxide film 10 and that for the area with no oxide film 10 differs by more than 5 times.

Further, the thickness of the oxide film 10 is basically decided depending on the required duration of the difference in Wetting Time. Accordingly, the thickness may be restricted as: “Duration of melted state of solder in a reflow oven in the bonding process”<“Time taken to remove the oxide film by flux”.

In practice, various combinations can be made depending on the types of flux and solder, setting condition for reflow temperature etc. The thickness of the oxide film 10 is set to a value greater than the reduced thickness of the oxide film by flux in the duration of melted state of solder in a reflow oven in the bonding process.

For example, the heating time is 50 nm/10 nm/per second for the oxide film 10 with a thickness=50 nm, according to the foregoing report, and therefore, the reflow oven should be set so that “duration of the temperature in which the solder is melted is less than five seconds”. Accordingly, the thickness of the oxide film 10 is preferably greater than “Duration of temperature greater than fusing point of solder (sec)×10 (nm/sec). Further, the value may be multiplied by a safety factor (e.g., to make the thickness of the remaining oxide film 10 to at least 10 nm, more preferably to 10 nm-20 nm).

### INDUSTRIAL APPLICABILITY

The present invention provides a semiconductor device and the manufacturing method thereof that achieve secure formation of an external electrode terminal with use of a solder ball that contributes cost reduction, thereby improving reliability of a semiconductor device of CSP structure or the like. Further, the present invention allows omission of a process for the conventional insulation film. On this account, the present invention is suitably used for a field of semiconductor devices employed for various communication devices, such as a mobile phone, or various electronic devices, such as a liquid crystal display device.

A semiconductor device according to the present invention comprises: a substrate; an electric circuit formed on an element-formed surface of the substrate; an electrode pad electrically conducted to the electric circuit; a wiring pattern re-wired by being electrically conducted to the electrode pad; and an oxide film formed on a surface of the wiring pattern, the oxide film being formed by subjecting the wiring pattern to oxidization.

With this arrangement in which an oxide film is formed on the surface of the wiring pattern, when an external electrode terminal is formed on the wiring pattern from solder, the spread of the melted solder on the wiring pattern is prevented by the oxide film, that has a poor wettability with respect to the melted solder, thereby allowing secure formation of external electrode terminal on the wiring pattern.

Moreover, in the foregoing arrangement, since the oxide film is formed by subjecting the wiring pattern to oxidization, an extra process for forming the conventional insulation film is not required, thereby reducing fabrication cost.

In the foregoing semiconductor device, it is preferable that the wiring pattern contains copper as a main component. With this arrangement in which the wiring pattern is formed from a material mainly containing copper, it becomes possible to more easily form the oxide film, and also to remove the oxide film, thus allowing secure formation of external electrode terminal with the use of solder.

In the foregoing semiconductor device, it is preferable that the wiring pattern thereon has an external electrode terminal. In the foregoing semiconductor device, the external electrode terminal may be a solder ball, that is created by shaping solder to a substantially round. In the foregoing semiconductor device, it is preferable that the external electrode terminal has poor wettability with respect to the oxide film. In the foregoing semiconductor device, it is preferable that the oxide film is provided on the wiring pattern outside an area for the external electrode terminal.

The foregoing semiconductor device may be arranged so that the external electrode terminal includes either (i) a substantially round resin and solder for covering the resin, or (ii) a substantially round metal and solder for covering the metal. The foregoing semiconductor device may be arranged so that the substantially round metal contains copper or a copper alloy. The foregoing semiconductor device may be arranged so that the oxide film is provided on a region adjacent to a region where the external electrode terminal is formed.

In order to solve the foregoing problems, a manufacturing method of semiconductor device according to the present invention comprises the steps of: (a) forming a wiring pattern for allowing electrical conduction of an electric pad and an:external electrode terminal with respect to an element-formed surface of a wafer of a semiconductor device; (b) forming an oxide film on the wiring pattern in an area other than an area for the external electrode terminal, through oxidization of the wiring pattern; and (c) forming the external electrode terminal on the wiring pattern.

With this arrangement in which the oxide film is formed on the wiring pattern avoiding the mounting region of the external electrode terminal, when an external electrode terminal is formed on the wiring pattern from solder, the spread of the melted solder onto the wiring pattern upon formation of the external electrode terminal is prevented by the oxide film, that has a poor wettability with respect to the melted solder, thereby allowing secure formation of external electrode terminal on the wiring pattern.

Moreover, in the foregoing method, since the oxide film is formed by subjecting the wiring pattern to oxidization, an extra process for forming the conventional insulation film is not required, thereby reducing fabrication cost.

The foregoing method may be arranged such that: the step (b) comprises the substeps of: (i) forming a whole area oxide film by subjecting a whole surface of the wiring pattern to oxidization; and (ii) removing the whole area oxide film only for a portion corresponding to the area for the external electrode terminal oxide film, from the wiring pattern. The foregoing method may be arranged such that: the substep (ii) is performed with a dilute sulfuric acid. The foregoing method may be arranged such that: in the substep (ii), the portion of the whole area oxide film is removed by dry etching.

The foregoing method may be arranged such that: the step (b) comprising the substeps of: (i) forming a mask layer on a surface of the wiring pattern in the area for the external electrode terminal; and (ii) forming an oxide film through oxidization of the surface of the wiring pattern having the mask layer.

The foregoing method may be arranged such that: in the substep (ii), the oxide film is formed on the surface of the wiring pattern by subjecting the surface of the wiring pattern to heating oxidization. The foregoing method may be arranged such that: the oxide film is formed on the surface of the wiring pattern by subjecting the surface of the wiring pattern to chemical processing. The foregoing method may be arranged such that: the chemical processing is performed with hydrogen peroxide.

[Effect of the Invention]

As described, a semiconductor device according to the present invention comprises an oxide film that is formed on a surface of wiring pattern re-wired by being electrically conducted to an electric pad electrically conducted to an electric circuit, the oxide film being formed by subjecting the wiring pattern to oxidization.

With this arrangement in which an oxide film is provided on the surface of the wiring pattern, when an external electrode terminal is formed on the wiring pattern from solder, the spread of the melted solder on the wiring pattern is prevented by the oxide film, that has a poor wettability with respect to the melted solder. On this account, the present invention provides an effect of secure formation of external electrode terminal on the wiring pattern.

Moreover, in the foregoing arrangement, since the oxide film is formed by subjecting the wiring pattern to oxidization, an extra process for forming the conventional insulation film is not required. On this account, the present invention provides an effect of reduction in fabrication cost.

As described, a manufacturing method of semiconductor device according to the present invention is performed by forming an oxide film on wiring pattern that is provided for allowing electrical conduction of an electric pad and an external electrode terminal with respect to an element-formed surface of a wafer of a semiconductor device, the oxide film being formed outside the mounting region of the external electrode terminal, through oxidization of the wiring pattern.

With this arrangement in which the oxide film is formed on the wiring pattern avoiding the mounting region of the external electrode terminal, when an external electrode terminal is formed on the wiring pattern from solder, the spread of the melted solder onto the wiring pattern upon formation of the external electrode terminal is prevented by the oxide film, that has a poor wettability with respect to the melted solder. On this account, the present invention provides an effect of secure formation of external electrode terminal on the wiring pattern.

Moreover, in the foregoing method, since the oxide film is formed by subjecting the wiring pattern to oxidization, an extra process for forming the conventional insulation film is not required. On this account, the present invention provides an effect of reduction in fabrication cost.

The embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

1. A semiconductor device, comprising:
a substrate;
an electric circuit formed on an element-formed surface of the substrate;
an electrode pad electrically conducted to the electric circuit;
a wiring pattern re-wired by being electrically conducted to the electrode pad; and
an oxide film formed on a surface of the wiring pattern, the oxide film being formed by subjecting the wiring pattern to oxidization.

2. The semiconductor device as set forth in claim 1, wherein:
the wiring pattern contains copper as a main component.

3. The semiconductor device as set forth in claim 1, wherein:
the wiring pattern thereon has an external electrode terminal.

4. The semiconductor device as set forth in claim 3, wherein:
the external electrode terminal is a solder ball, that is created by shaping solder to a substantially round.

5. The semiconductor device as set forth in claim 3, wherein:
the external electrode terminal has poor wettability with respect to the oxide film.

6. The semiconductor device as set forth in claim 3, wherein:
the oxide film is provided on the wiring pattern outside an area for the external electrode terminal.

7. The semiconductor device as set forth in claim 3, wherein:
the external electrode terminal includes either (i) a substantially round resin and solder for covering the resin, or (ii) a substantially round metal and solder for covering the metal.

8. The semiconductor device as set forth in claim 7, wherein:
the substantially round metal contains copper or a copper alloy.

9. The semiconductor device as set forth in claim 3, wherein:
the oxide film is provided on a region adjacent to a region where the external electrode terminal is formed.

10. A manufacturing method of a semiconductor device, comprising the steps of:
(a) forming a wiring pattern for allowing electrical conduction of an electric pad and an external electrode terminal with respect to an element-formed surface of a wafer of a semiconductor device;
(b) forming an oxide film on the wiring pattern in an area other than an area for the external electrode terminal, through oxidization of the wiring pattern; and
(c) forming the external electrode terminal on the wiring pattern.

11. The manufacturing method of a semiconductor device as set forth in claim 10, wherein:
the step (b) comprises the substeps of:
(i) forming a whole area oxide film by subjecting a whole surface of the wiring pattern to oxidization; and
(ii) removing the whole area oxide film only for a portion corresponding to the area for the external electrode terminal oxide film, from the wiring pattern.

12. The manufacturing method of a semiconductor device as set forth in claim 11, wherein:
the substep (ii) is performed with a dilute sulfuric acid.

13. The manufacturing method of a semiconductor device as set forth in claim 11, wherein:
in the substep (ii), the portion of the whole area oxide film is removed by dry etching.

14. The manufacturing method of a semiconductor device as set forth in claim 10, wherein:
the step (b) comprising the substeps of:
(i) forming a mask layer on a surface of the wiring pattern in the area for the external electrode terminal; and
(ii) forming an oxide film through oxidization of the surface of the wiring pattern having the mask layer.

15. The manufacturing method of a semiconductor device as set forth in claim 10, wherein:
in the substep (ii), the oxide film is formed on the surface of the wiring pattern by subjecting the surface of the wiring pattern to heating oxidization.

16. The manufacturing method of a semiconductor device as set forth in claim 10, wherein:
the oxide film is formed on the surface of the wiring pattern by subjecting the surface of the wiring pattern to chemical processing.

17. The manufacturing method of a semiconductor device as set forth in claim 16, wherein:
the chemical processing is performed with hydrogen peroxide.
